(19) United States
(12) Patent Application Publication
(10) Pub. No.: US 2024/0077312 A1
(43) Pub. Date: Mar. 7, 2024

(54) SYSTEMS AND METHODS FOR ACOUSTICALLY ISOLATED RESONATORS

(71) Applicant: Panasonic Intellectual Property Management Co., Ltd., Osaka (JP)

(72) Inventors: Diego EMILIO SERRANO, Peachtree, GA (US); Sagnik PAL, Marlborough, MA (US); Amir RAHAFROOZ, Shaker Heights, OH (US); Thomas Kieran NUNAN, Carlisle, MA (US); Ijaz JAFRI, Holliston, MA (US)

(21) Appl. No.: 17/930,173

(22) Filed: Sep. 7, 2022

(51) Int. Cl. G01C 19/5698

(52) U.S. Cl. CPC G01C 19/5698

(57) ABSTRACT

Systems and methods disclosed herein include a device with a bulk acoustic wave resonator and one or more trenches that are configured to impede the flow of acoustic energy to the bulk acoustic wave resonator.

### TECHNICAL FIELD

The present disclosure relates to acoustically isolated resonators, and more particularly, to systems and methods for acoustically isolated bulk wave resonator gyroscopes.

### BACKGROUND

The coupling of acoustic energy to a resonator can increase the noise of the resonator. Variation of coupled acoustic energy can cause variation in resonator output. This causes degradation of the resonator performance. These and other deficiencies exist.

### BRIEF SUMMARY

Embodiments of the present disclosure provide a device that includes a substrate. The device may include a bulk acoustic wave resonator that is arranged on at least a first surface of the substrate. The substrate may include one or more trenches that are configured to impede the flow of acoustic energy to the bulk acoustic wave resonator.

Embodiments of the present disclosure provide a device that includes a plurality of device components. A first device component selected from the plurality of device components may comprise a plurality of trenches and/or cavities. A second device component selected from the plurality of device components may be sensitive to acoustic energy. The plurality of trenches are configured to impede the flow of the acoustic energy to the second device component.

Embodiments of the present disclosure provide a device that includes a substrate. The device may include a resonator that is coupled to a first surface of the substrate. The resonator may include a bulk acoustic wave resonator gyroscope that is capacitively transduced via one or more electrodes. The device may include a cap structure. The cap structure may include one or more trenches that are configured to impede the flow of the acoustic energy to the resonator. The cap structure may include one or more cavities that are configured to impede the flow of the acoustic energy to the resonator.

### BRIEF DESCRIPTION OF THE DRAWINGS

FIG. 1A illustrates a cross-sectional view of a device according to an example embodiment, FIG. 1B illustrates a cross-sectional view of a device according to another example embodiment.

FIG. 2 illustrates a cross-sectional view of a device according to another example embodiment.

FIGS. 3A-3B illustrate a cross-sectional view of a device according to another example embodiment.

FIG. 4 illustrates a cross-sectional view of a device according to another example embodiment.

FIGS. 5A-5H illustrate a plan view of various patterns according to an example embodiment.

FIG. 6 illustrates a cross-sectional view of a device according to another example embodiment.

FIG. 7 illustrates a cross-sectional view of a device according to another example embodiment.

FIG. 8 illustrates a graph of a figure of merit and a trench dimension according to an example embodiment.

FIGS. 9A-9C illustrate die attach patterns according to an example embodiment.

### DETAILED DESCRIPTION

The following description of embodiments provides non-limiting representative examples referencing numerals to particularly describe features and teachings of different aspects of the invention. The embodiments described should be recognized as capable of implementation separately, or in combination, with other embodiments from the description of the embodiments. A person of ordinary skill in the art reviewing the description of embodiments should be able to learn and understand the different described aspects of the invention. The description of embodiments should facilitate understanding of the invention to such an extent that other implementations, not specifically covered but within the knowledge of a person of skill in the art having read the description of embodiments, would be understood to be consistent with an application of the invention.

Acoustic energy may get coupled to a resonator and thereby degrade its performance. For example, the acoustic energy may increase the noise of the resonator, or impact the zero-rate-offset of a resonator-based gyroscope. Further, temperature-dependent acoustic energy coupling to the resonator may produce temperature dependent effects, for example, high-order zero-rate-offset versus temperature behavior. Besides temperature, the unwanted acoustic energy coupling may vary with other operating conditions, such as stress or external fields, which may degrade device performance. The sources of the unwanted acoustic energy may be internal or external to the device. The acoustic energy may be generated in the resonator and electrodes due to electrostatic transduction. Thus, in some examples, the resonator and the electrode may serve as severe sources of acoustic energy.

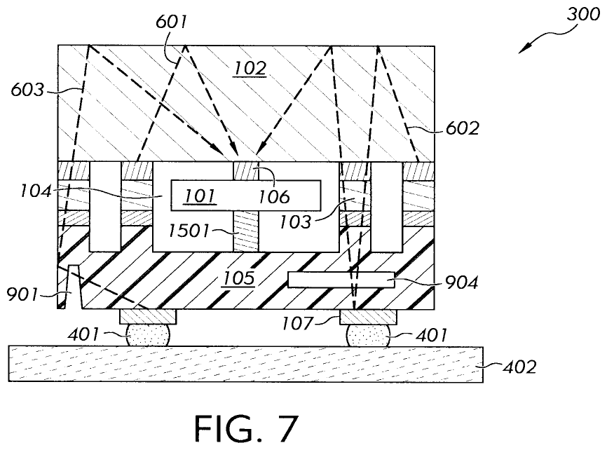

As used herein, unwanted acoustic energy may refer to acoustic energy, which may or may not be external to the resonator 101, coupled to the anchor 106, even if generated internal to the resonator 101. Thus, unwanted acoustic energy may be generated from within the resonator 101 and/or the environment outside the resonator 101, and thus is not limited to energy that is only external to the resonator 101, and the trench(es), such as trench 901, is configured to impede a flow, including but not limited to one or more flow paths, of the unwanted acoustic energy when bounced back, as further discussed herein. In some examples, unwanted acoustic energy may couple into the resonator 101 via structures, such as other than an anchor 106, including but not limited to a connection 1501 (as depicted in, for example, FIG. 7). In some examples, there may be unwanted acoustic energy coupling to the resonator 101 via a medium that surrounds the resonator. By way of example, the medium may refer to a gas, a liquid, and/or any combination thereof that is located around the resonator 101. Without limitation, the medium may be external to the resonator 101.

To mitigate these problems, the trenches and/or the cavities of the systems and method disclosed herein may be arranged to impede a flow, such as one or more flow paths, and reduce unwanted acoustic energy between drive and sense modes of a gyroscope, such as a bulk acoustic wave resonator gyroscope. Moreover, such an arrangement reduces zero-rate-offset and high-order zero-rate-offset vs. temperature behavior in resonant gyroscopes. Consequently, this yields enhancement in device performance.

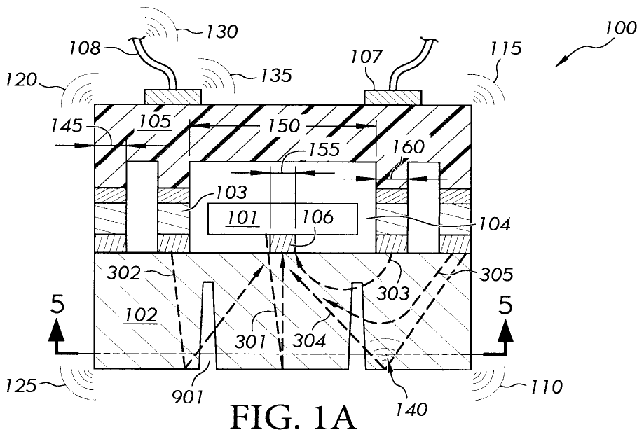

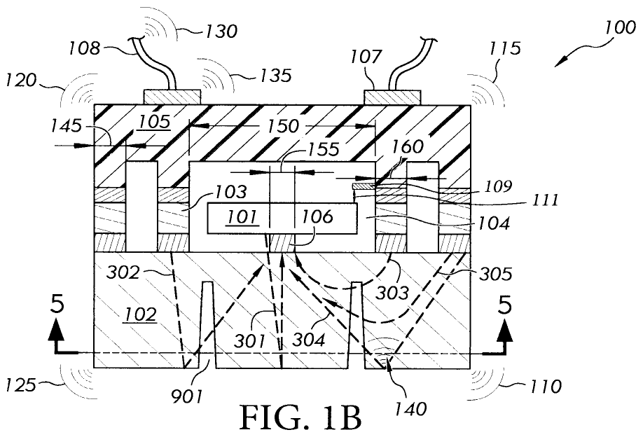

FIG. 1A depicts a cross-sectional view of a device 100 according to an example embodiment. The device 100 may include a resonator 101, a substrate 102, an electrode 103, a transduction gap 104, a cap structure 105, an anchor 106, a bond pad 107, a wire bond 108, and one or more trenches 901. Although FIG. 1A illustrates single instances of the components of the device 100, it is understood that any number of components of the device 100 may be included.

As further depicted in FIG. 1A, acoustic energy may be supplied from several sources, such as sources 110, 115, 120, and 125 that are external to the device 100, source 130 due to motion of the wire bond 108, source 135 due to motion of the bond pad 107, source 140 due to motion of the substrate 102, source 145 due to motion of the cap structure 105, source 150 due to motion of the resonator, source 155 due to motion of the anchor 106, and source 160 due to motion of the electrode 103. The arrows depict motion of the sources 145, 150, 155, and 160 but do not necessarily depict the direction of the motion, as the motion or vibration can occur in any direction, such as longitudinally, laterally, sideways, obliquely, tortuously, etc. As further described below, the device 100 may be configured to isolate the resonator 101 from unwanted acoustic energy and enhance its performance.

The resonator 101 may comprise a bulk acoustic wave resonator gyroscope. The bulk acoustic wave resonator may be arranged on at least a first surface of the substrate 102. For example, the resonator 101 may be connected to the first surface of the substrate 102 via an anchor 106. The resonator 101 may be capacitively transduced via the one or more electrodes 103. In some examples, the one or more electrodes 103 may comprise one or more peripheral electrodes. In other examples, the one or more electrodes 103 may comprise one or more non-peripheral electrodes. In still other examples, the one or more electrodes 103 may comprise a peripheral electrode, a non-peripheral electrode, and/or any combination thereof. For example, FIG. 1B illustrates a device 100, which further includes a non-peripheral electrode 109. In some examples, the non-peripheral electrode 109 may include a planar electrode. Capacitive transduction may occur between the non-peripheral electrode 109 and resonator 101 across gap 111. Although FIG. 1B illustrates single instances of the components of the device 100, it is understood that any number of components of the device 100 may be included. FIG. 1B may reference the same components of device 100 as discussed above with respect to FIG. 1A. The transduction gap 104 may separate the resonator 101 from the one or more electrodes 103. The transduction gap 104 may be disposed above the substrate 102. For example, the transduction gap 104 may be disposed above the first surface of the substrate 102.

The wire bond 108 may be coupled to the bond pad 108. The bond pad 108 may be disposed on a first surface of the cap structure 105. In some examples, the bond pad 108 may be disposed on opposite ends of the first surface of the cap structure 105.

The substrate 102 may include one or more trenches 901 that are configured to impede a flow of unwanted acoustic energy to the bulk acoustic wave resonator. For example, the one or more trenches 901 may be symmetrically disposed within the substrate 102. In another example, the one or more trenches 901 may be asymmetrically disposed within the substrate 102. Moreover, the one or more trenches 901 may be of same shape or different shape than another trench 901. Further, the one or more trenches 901 may be of same or different size than another trench 901. For example, at least one trench 901 may extend more than halfway into the substrate 102, including but not limited to in a direction perpendicular to the substrate 102. The length of the trench 901 may exceed the width of the trench 901. In other examples, the length of the trench 901 may be the same or smaller than the width of the trench 901.

The one or more trenches 901 may be configured to impede the flow of unwanted acoustic energy to the resonator 101. In some examples, the presence of the one or more trenches 901 may be configured to impede a flow of unwanted acoustic energy, such as one or more flow paths 302, 303, 304, and/or 305, to the resonator 101 via anchor 106. As depicted in FIGS. 1A-1B, acoustic energy originating at one or more of the electrodes 103 or cap structure 105 may traverse respective direct flow paths 303, 305 to the resonator 101. The acoustic energy originating at one or more of the electrodes 103 or cap structure 105 may traverse respective flow paths 302, 304 to the resonator 101 after one or more reflections, such as a reflection against a second surface, such as the bottom surface, of the substrate 102. It is understood that the reflection not be limited to only a single reflection or with respect to the second surface of the substrate 102, and that additionally or alternatively, any number of reflections and/or any number of surfaces of the substrate 102 may be reflected against to constitute a flow path for the acoustic energy to traverse to the resonator 101.

The one or more trenches 901 may be formed by one or more processes, including but not limited to dry etching, wet etching, dicing, laser ablation, milling, and/or any combination thereof. Moreover, any number of the walls of trenches 901 may be straight, tapered, rounded, corrugated, undulating, and/or any combination thereof.

The resonator 101 may be configured to resonate in a plurality of modes, such as a first mode and a second mode. Under the first mode, such as a drive mode, this may correspond to vibration along a first axis, whereas under the second mode, such as a sense mode, that may correspond to vibration along a second axis and thus these modes are orthogonal to each other. It is generally desirable for the frequencies of the drive and sense modes to match, as this may tend to increase signal-to-noise ratio of the resonator 101. For example, an angular rate gyroscope may be configured to operate in a mode-matching condition such that the drive mode is configured to have the same resonant frequency as the sense mode. In some examples, unwanted acoustic coupling between drive and sense modes may occur via flow path 301. In this manner, acoustic energy originating at the resonator 101 due to drive mode excitation may traverse flow path 301 and get coupled back to the sense mode of the resonator 101. In mode-matched configuration, the impact of such coupling is especially deleterious as both modes are nominally at about the same frequency thereby resulting in efficient coupling of unwanted acoustic energy.

The cap structure 105 may be configured to at least partially encompass the resonator 101. The transduction gap 104 may include a separation or gap between the resonator 101 and one or more electrodes 103. In some examples, the device 100 may include two or more transduction gaps 104. For example, two transduction gaps 104 may be diametrically opposite to each other, and may be each relative to the resonator 101 and different electrodes 103. The resonator 101 and the one or more electrodes 103 may be formed in, for example, a base portion of the device 100, and the base portion may be bonded to the cap structure 105. The cap structure 105 may be disposed above the substrate 102. For example, the cap structure 105 may be disposed above the first surface of the substrate 102.

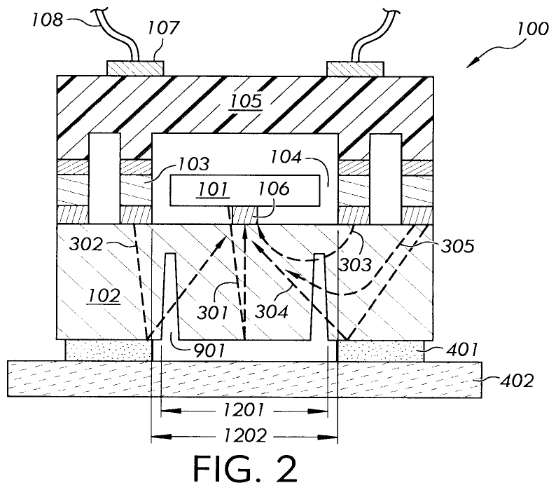

FIG. 2 depicts a cross-sectional view of a device 100 according to another example embodiment. FIG. 2 may reference the same components of device 100 as discussed above with respect to FIGS. 1A-1B. For purposes of brevity, the description of the components of device 100 discussed above with respect to FIGS. 1A-1B as applied to FIG. 2 is omitted. Although FIG. 2 illustrates single instances of the components of the device 100, it is understood that any number of components of the device 100 may be included. The device 100 may include one or more attachment structures 401. For example, at least one of the attachment structures 401 may be disposed below a second surface, such as the bottom surface, of the substrate 102. The one or more attachment structures 401 may include one or more selected from the group of: a soft die attach, a hard die attach, an adhesive, a stud bump, an interposer, and/or any combination thereof. In particular, soft materials, including but not limited to a soft-die, may be used to avoid buildup of stress when temperature changes. For example, soft-die attach material may be utilized to minimize thermal and packaging stresses acting on the MEMS die. When selecting a type of die attach, there is consideration for a tradeoff between stress effect and reliability, as the softer the die attach, the less reliable it is likely to be. Absent the utilization of trenches in the resonator 101, the problem regarding unwanted acoustic energy exists (as discussed herein), but the factors for consideration in selecting the soft die attach include lower stress during packaging and operation across a range of temperatures. In some examples, die attach thickness values may range from a few microns to a few hundred microns. For example, the die attach thickness value may comprise 50 microns.

In some examples, the one or more attachment structures 401 may be disposed at opposite ends of the substrate 102. For example, the one or more attachment structures 401 may be disposed symmetrically with respect to the opposite ends of the substrate 102. The one or more attachment structures 401 may include a width that is shorter than an end of the substrate 102 that it is coupled to. In other example, the one or more attachment structures 401 may include a width that is longer than an end of the substrate 102 that it is coupled to. In some examples, the one or more attachment structures 401 may be disposed adjacent or closer to an outer edge, as opposed to an inner edge, of the one or more trenches 901.

The device 100 may include one or more underlying support structures 402. In some examples, the device 100 may include a single underlying support structure 402. For example, the underlying support structure 402 may be disposed between the one or more attachment structures 401. In some examples, the underlying support structure may extend longer than the length of each of the substrate 102 and cap structure 105. The one or more underlying support structures 402 may include at least one selected from the group of an integrated circuit, a printed circuit board, a package, an interposer, or the like.

As further depicted in FIG. 2, a first dimension 1201 may be smaller than a second dimension 1202, and relative to a direction parallel to the one or more underlying support structures 402. For example, the first dimension 1201 may be defined by a first distance from a first end, such as an outer edge, of a first trench 901 to a second end, such as an outer edge, of a second trench 901. In some examples, the outer edges of the trench 901 may include edges that are furthest away relative to the resonator 101. The second dimension 1202 may be defined by a second distance from a third end, such as an inner end of a first electrode 103 to a fourth end, such as an inner end of a second electrode 103. In some examples, the inner ends of the electrodes 103 may include ends that are closed to the resonator 101. In some examples, the device 100 may include two or more transduction gaps 104 that may be diametrically opposite to each other, and may be each relative to the resonator 101 and different electrodes 103. In some examples, selecting the first dimension 1201 as being smaller than the second dimension 1202 may impede unwanted acoustic energy flow via flow paths 302, 303, and 305.

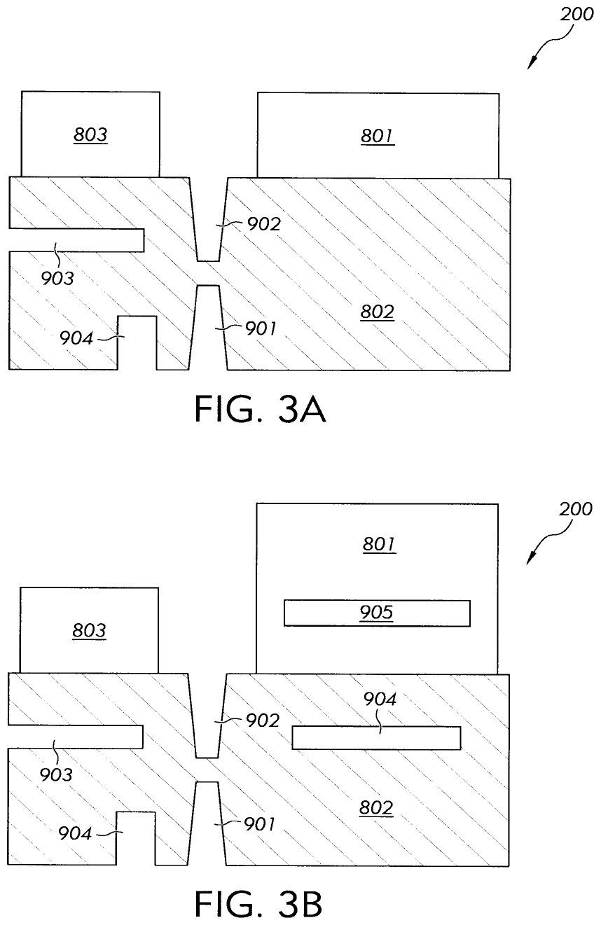

FIGS. 3A-3B each depict a cross-sectional view of a device 200 according to an example embodiment. FIGS. 3A-3B may reference the same components of device 100 as discussed above with respect to FIGS. 1 and 2. For purposes of brevity, the description of the components of devices 100 discussed above with respect to FIGS. 1 and 2 as applied to FIG. 3 is omitted. Although FIGS. 3A-3B illustrates single instances of the components of the device 200, it is understood that any number of components of the device 200 may be included.

As illustrated in FIG. 3A, the device 200 may include a plurality of device components 801, 802, and 803. For example, the device component 801 and the device component 803 may be disposed on the same surface of the device component 802. In some examples, the device component 801 and the device component 803 may be disposed on opposite ends of a first surface of the device component 802.

At least one of the device components, such as the device component 802, selected from the plurality of device components 801, 802, and 803 may comprise a plurality of trenches 901, 902, 903, and 904. At least one of the device components, such as the device component 801, may be sensitive to unwanted acoustic energy. The plurality of trenches 901, 902, 903, and 904 may be configured to impede a flow of the unwanted acoustic energy to the device component 801. The device component 801 may be separated from the device component 803 by at least one trench, such as trench 902. In some examples, the trench 901 may be of a different size and/or shape as the trenches 902, 903, and 904. As previously explained, the unwanted acoustic energy may be supplied from any of several sources that are external and/or internal to the device 200.

The plurality of trenches 901, 902, 903, and 904 may be formed by one or more processes, including but not limited to dry etching, wet etching, dicing, laser ablation, milling, and/or any combination thereof. Moreover, any number of the walls of trenches 901, 902, 903, and 904 may be straight, tapered, rounded, corrugated, undulating, and/or any combination thereof.

As illustrated in FIG. 3B, the device 200 may include a plurality of device components 801, 802, and 803, just as depicted in FIG. 3A. In addition, at least one of the device components 801 may comprise a bulk acoustic wave resonator 905 that is capacitively transduced by one or more electrodes. Thus, the device 200 may include a bulk acoustic wave resonator 905 that is capacitively transduced by one or more electrodes, such as one or more peripheral electrodes. In addition, the device 200 may include a cavity 904. For example, the device component 802 may be configured to include a cavity 904 that is disposed below the bulk acoustic wave resonator 905. The cavity 904 may be configured to impede the flow of the acoustic energy into the bulk acoustic wave resonator 905. The cavity 904 may be adjacent to at least one of the trenches, such as trench 902. The cavity 904 may be of any size and/or shape. In effect, the plurality of trenches 901, 902, 903, and 904 and one or more cavities 904 may be configured to mitigate the unwanted acoustic energy flow into the bulk acoustic wave resonator 905.

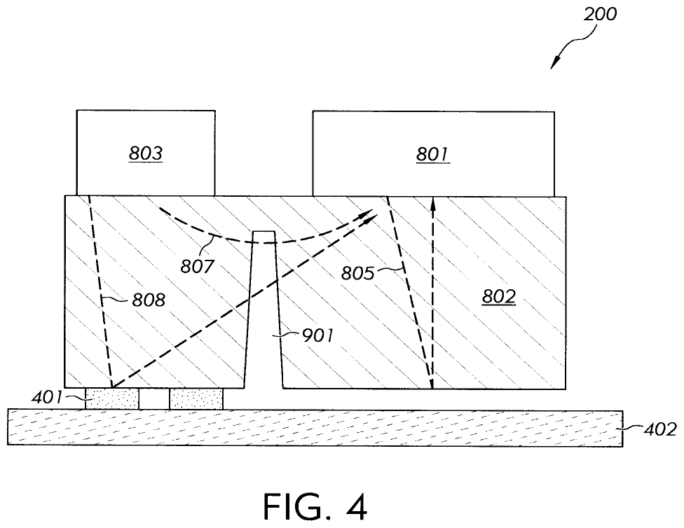

FIG. 4 depicts a cross-sectional view of a device 200 according to an example embodiment. FIG. 4 may reference the same components of device 100 as discussed above with respect to FIGS. 1 and 2, and device 200 as discussed above with respect to FIGS. 3A-3B. For purposes of brevity, the description of the components of devices 100 discussed above with respect to FIGS. 1 and 2, and the components of devices 200 as discussed above with respect to FIGS. 3A-3B as applied to FIG. 4 is omitted. Although FIG. 4 illustrates single instances of the components of the device 200, it is understood that any number of components of the device 200 may be included.

The device 200 may include a plurality of device components 801, 802, and 803, one or more attachment structures 401, and one or more underlying support structures 402. For example, the device component 801 and the device component 803 may be disposed on the same surface of the device component 802. In some examples, the device component 801 and the device component 803 may be disposed on opposite ends of a first surface of the device component 803.

The device component 802 may comprise one or more trenches, such as trench 901. For example, at least one trench 901 may extend more than halfway into the device component 802, including but not limited to in a direction perpendicular to the underlying support structure 402. The length of the trench 901 may exceed the width of the trench 901. In other examples, the length of the trench 901 may be the same or smaller than the width of the trench 901.

The trench 901 may be configured to impede the flow of unwanted acoustic energy from device component 803 and reflected energy from the one or more attachment structures 401. For example, as indicated in flow path 808, the unwanted acoustic energy may originate from device component 803 which is reflected by the one or more attachment structures 401 before it is impeded by the trench 901 that is destined to reach the device component 801.

As indicated in flow path 807, the unwanted acoustic energy may originate from device component 803 before it is impeded by the trench 901 that is destined to reach the device component 801.

As indicated in flow path 805, the unwanted acoustic energy may originate from the device component 802 which is reflected by a surface, such as the bottom surface, of the device component 802 that is destined to reach the device component 801.

If the acoustic energy reflectivity at the one or more attachment structures 401 is high or varies significantly with operating conditions, such as temperature, stress, an external magnetic field, or the like, the one or more attachment structures 401 may be configured with small discrete geometries. In this manner, this configuration may mitigate unwanted acoustic energy coupling to device component 801, as well as variation of the acoustic energy coupling to device component 801 across the range of operating conditions.

The one or more attachment structures 401 may be disposed on a first surface, such as a bottom surface, of the second device component 802. In some examples, the one or more attachment structures 401 may be disposed adjacent to each other on the same side of the device component 802. In some examples, the one or more attachment structures 401 may be of the same size and/or shape. The one or more attachment structures 401 may be disposed below the device component 803. At least one of the one or more attachment structures 401 may be disposed adjacent, below, and/or close to an outer edge of the trench 901. In some examples, there may be no attachment structure 401 that is in a direct line-of-sight from the device component 801. In this manner, this configuration may reduce the intensity of acoustic energy traversing the flow path 805 and/or mitigate variation of unwanted acoustic energy coupled to the device component 801 across the range of operating conditions.

The underlying support structure 402 may be coupled to the first surface, such as the bottom surface, of the second device component 802 via the one or more attachment structures 401.

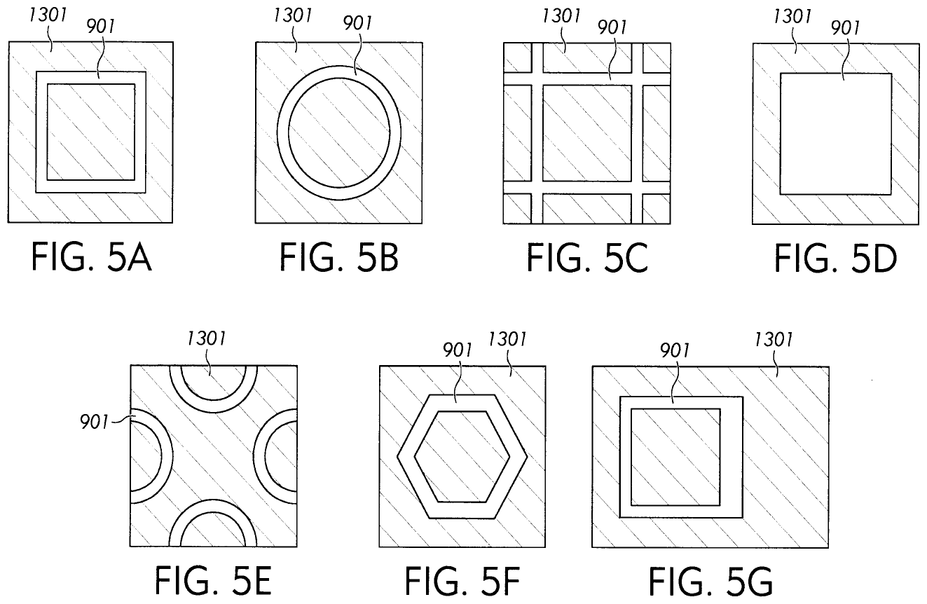

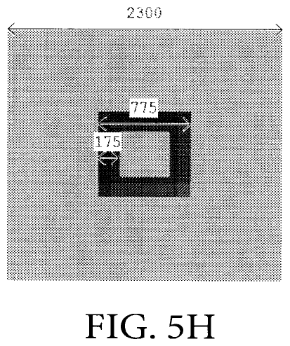

FIGS. 5A-5H illustrate various designs of a trench in a plan view according to an example embodiment. The trench may refer to the same trench as previously described above with respect to any of FIGS. 1-4. Any number and any combination of these trench designs may be used for the trenches in connection with any figures disclosed herein. As depicted in these figures, a trench region 901 may be surrounded by one or more solid regions 1301 of the device 100 or device 200.

FIG. 5A illustrates a square trench region 901 that is disposed between solid regions 1301. FIG. 5B illustrates a circular trench region 901 that is disposed between solid regions 1301. FIG. 5C illustrates a cross trench region 901 that is disposed between solid regions 1301. FIG. 5D illustrates a square trench region 901 that is disposed inside a solid region 1301. FIG. 5E illustrates partially circular trench regions 901 that are disposed between solid regions 1301. For example, a convex trench pattern, as depicted in FIG. 5E, may be configured to reduce a magnitude of unwanted acoustic energy at the device component 801, resonator 101, or the capacitively transduced bulk acoustic wave resonator 905. FIG. 5F illustrates a hexagonal trench region 901 that is disposed between solid regions 1301. FIG. 5G illustrates a polygonal trench region 901 that is disposed between solid regions 1301. FIG. 5H illustrates an example dimensions of a square trench region 901 that is disposed between solid regions 1301. The trench region 901 and solid regions 1301 may be the same or different as the respective regions illustrated in FIG. 5A. In some examples, the square trench region 901 may include about 775 microns in a first x dimension, and 175 microns in a second x dimension. The solid region 1301 may include about 2300 microns in a third x dimension. In some examples, the trench 901 region may be about 10-500 microns deep. By way of example, a range of a ratio relative to the area inside the region 901 and the area outside the region 901 may comprise approximately 0.03-0.09. However, it is understood that other values for the ratio relative to the respective areas inside and outside the region 901 are contemplated.

It is understood that the trench regions 901 and the solid regions 1301 of FIGS. 5A-5H are not limited to only these trench patterns and/or shapes and/or sizes, and that any other trench patterns and/or shapes and/or sizes may be used in order to at least partially cancel acoustic waves that may or may not be reflected. In some examples, the trench patterns of FIGS. 5A-5H may be symmetric with respect to the device component 801, resonator 101, or the capacitively transduced bulk acoustic wave resonator 905. For example, by having the one or more attachment structures 401 (including but not limited to a soft-die attach) in contact with region 1301 outside the trench region 901, unwanted acoustic energy flow, from the one or more attachment structures 401 to the resonator 101, may be impeded. In other examples, the trench patterns of FIGS. 5A-5H may be asymmetric with respect to the device component 801, resonator 101, or the capacitively transduced bulk acoustic wave resonator 905. For example, an asymmetric trench pattern may be configured to partially cancel reflected acoustic waves at the device component 801, resonator 101, or the capacitively transduced bulk acoustic wave resonator 905 by destructive interference, as shown in FIG. 5G. In some examples, the asymmetric arrangement of the trench patterns, as shown in FIG. 5G, may achieve destructing interference of acoustic waves entering the resonator 101 via an achor 106, and this destructive interference may result in further mitigation of unwanted acoustic energy coupling to the resonator 101.

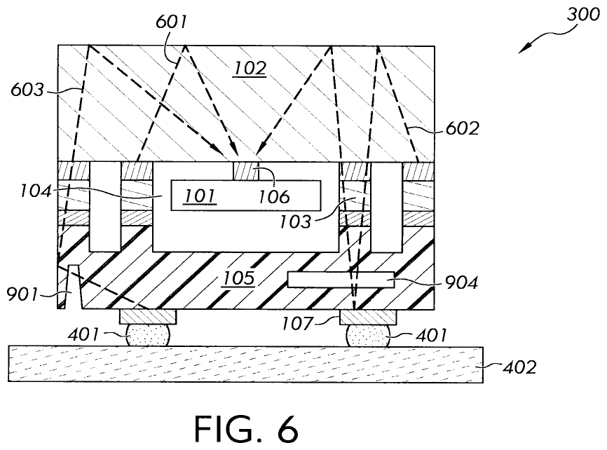

FIG. 6 illustrates a cross-sectional view of a device 300 according to an example embodiment.

FIG. 6 may reference the same components of device 100 as discussed above with respect to FIGS. 1 and 2, device 200 as discussed above with respect to FIGS. 3A-3B and FIG. 4, and the trench patterns as discussed above with respect to FIG. 5. For purposes of brevity, the description of the components of devices 100 discussed above with respect to FIGS. 1 and 2, and the components of devices 200 as discussed above with respect to FIGS. 3A-3B, and trench patterns of FIG. 5 as applied to FIG. 6 is omitted. Although FIG. 6 illustrates single instances of the components of the device 300, it is understood that any number of components of the device 300 may be included.

While the device 300 may include many of the same components as device 100 and/or device 200, it may differ in a few aspects. In particular, the substrate 102 may be disposed above the resonator 101. The cap structure 105 may be disposed below the resonator 101. The cap structure 105 may include one or more trenches 901 and one or more cavities 904 that may be configured to each impede one or more flow paths of unwanted acoustic energy that may or may not include reflections to the resonator 101. For example, the trench 901 and cavity 904 may be configured to mitigate the flow of unwanted acoustic energy to the resonator 101 via flow paths 603 and 602, respectively. The cavity 904 may be at least in the cap structure at least partially below the resonator.

In some examples, the unwanted acoustic energy may originate from the one or more bond pads 107 that may be reflected against a surface, such as a side surface, of the cap structure 105. The trench 901 may be arranged at a corner portion of the cap structure 105. The trench 901 may be disposed at an opposite end of the cavity 904. In some examples, the acoustic energy coupling may traverse flow path 601 from the electrode 103, reflect from a surface, such as a top surface, of the substrate 102 and into resonator 101.

In addition, the cap structure 105 may be coupled to the underlying support structure 402 via the bond pad 107 and one or more attachment structures 401. The one or more attachment structures 401 may be disposed on a first surface, such as the top surface, of the underlying support structure 402. The one or more attachment structures 401 may be disposed on a second surface, such as the bottom surface of the bond pad 107. The bond pad 107 may be disposed on a surface, such as on the bottom surface, of the cap structure 105. At least one of the one or more attachment structures 401 and/or the bond pad 107 may be disposed adjacent, below, and/or closer to an outer edge of the trench 901.

FIG. 7 illustrates a cross-sectional view of a device 300 according to an example embodiment.

FIG. 7 may reference the same components of device 100 as discussed above with respect to FIGS. 1 and 2, device 200 as discussed above with respect to FIGS. 3A-3B and FIG. 4, the trench patterns as discussed above with respect to FIG. 5, and the device 300 as discussed above with respect to FIG. 6. For purposes of brevity, the description of the components of devices 100 discussed above with respect to FIGS. 1 and 2, the components of devices 200 as discussed above with respect to FIGS. 3A-3B and FIG. 4, the trench patterns of FIG. 5, and device 300 as applied to FIG. 7 is omitted. Although FIG. 7 illustrates single instances of the components of the device 300, it is understood that any number of components of the device 300 may be included. While the device 300 may include many of the same components as device 300 of FIG. 6, it may differ in a few aspects. The resonator 101 may be dually connected to the substrate 102 and the cap structure 105. For example, the resonator 101 may be coupled to the substrate 102 via the anchor 106, such as to the bottom surface of the substrate 102 via the anchor 106. In addition, the resonator 101 may be coupled to the cap structure 105 via a connection 1501, such as to an upper surface of the cap structure 105 via the connection 1501. For example, the connection 1501 may refer to an electrical connection. In some examples, connection 1501 may comprise a pillar structure that may be configured to provide an anchoring point and an electrical connection. In some examples, the connection 1501 may be integrated with cap structure 105.

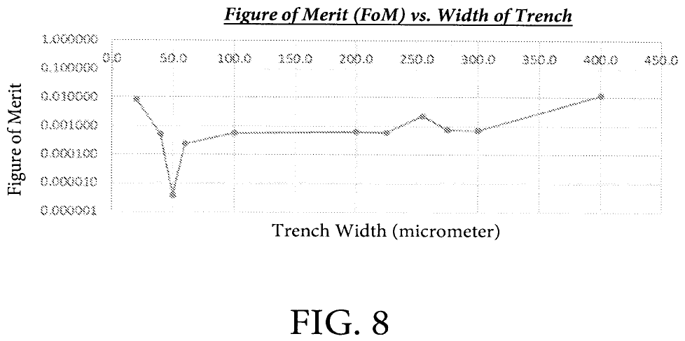

In addition, the present disclosure further considers the design and configuration of optimal trench dimensions that minimize unwanted acoustic energy to the resonator 101. For certain device parameters, a simulated optimal value of trench 901 width was about 50 microns. As illustrated in FIG. 8, a graph 800 illustrates a figure of merit and width of the trench region 901. For example, simulations conducted show an optimal value of trench width that minimized unwanted acoustic coupling. In some examples, the actual trench width used may be different from the simulated optimal value of trench width. More particularly, under operation of the simulations, the drive mode is excited and the sense mode is measured as a function of material properties of the one or more attachment structures 401. As the material property of the one or more attachment structures 401 is changed, the acoustic reflectivity is changed, and therefore the amplitude of the sense mode changes.

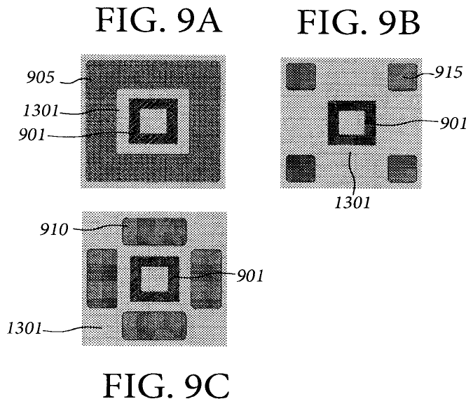

As the soft-die attach material have a low Young's modulus, the wavelength of acoustic waves in the die attach may be comparable to die attach thickness. Thus, acoustic thin-film interference effects may be prominent under certain conditions that result in high acoustic reflection and unwanted acoustic coupling. In some examples, the die attach may be distributed as a continuous pattern. In other examples, the die attach may be distributed as a set of discrete lines or dots. Exemplary die attach patterns are illustrated in FIGS. 9A-9C. It is noted that the area coverage of the die attach is a tradeoff between mechanical reliability of the attachment and unwanted acoustic coupling. FIG. 9A illustrates a plan view of a trench region 901 that is disposed between solid regions 1301, in which die attach pattern 905 is disposed continuously around relative to the trench region 901. FIG. 9B illustrates a plan view of a trench region 901 that is disposed between solid regions 1301, in which die attach pattern 915 is disposed at one or more edges or corners of the solid regions 1301. FIG. 9C illustrates a plan view of a trench region 901 that is disposed between solid regions 1301, in which die attach pattern 910 is disposed at one or more sides relative to the trench region 901.

Throughout the specification and the claims, the following terms take at least the meanings explicitly associated herein, unless the context clearly dictates otherwise. The term “or” is intended to mean an inclusive “or.” Further, the terms “a,” “an,” and “the” are intended to mean one or more unless specified otherwise or clear from the context to be directed to a singular form.

In this description, numerous specific details have been set forth. It is to be understood, however, that implementations of the disclosed technology may be practiced without these specific details. In other instances, well-known methods, structures and techniques have not been shown in detail in order not to obscure an understanding of this description. References to “some examples,” “other examples,” “one example,” “an example,” “various examples,” “one embodiment,” “an embodiment,” “some embodiments,” “example embodiment,” “various embodiments,” “one implementation,” “an implementation,” “example implementation,” “various implementations,” “some implementations,” etc., indicate that the implementation(s) of the disclosed technology so described may include a particular feature, structure, or characteristic, but not every implementation necessarily includes the particular feature, structure, or characteristic. Further, repeated use of the phrases “in one example,” “in one embodiment,” or “in one implementation” does not necessarily refer to the same example, embodiment, or implementation, although it may.

As used herein, unless otherwise specified the use of the ordinal adjectives “first,” “second,” “third,” etc., to describe a common object, merely indicate that different instances of like objects are being referred to, and are not intended to imply that the objects so described must be in a given sequence, either temporally, spatially, in ranking, or in any other manner.

While certain implementations of the disclosed technology have been described in connection with what is presently considered to be the most practical and various implementations, it is to be understood that the disclosed technology is not to be limited to the disclosed implementations, but on the contrary, is intended to cover various modifications and equivalent arrangements included within the scope of the appended claims. Although specific terms are employed herein, they are used in a generic and descriptive sense only and not for purposes of limitation.

This written description uses examples to disclose certain implementations of the disclosed technology, including the best mode, and also to enable any person skilled in the art to practice certain implementations of the disclosed technology, including making and using any devices or systems and performing any incorporated methods. The patentable scope of certain implementations of the disclosed technology is defined in the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A device comprising:
a substrate; and
a bulk acoustic wave resonator arranged on at least a first surface of the substrate, wherein the substrate includes one or more trenches that are configured to impede the flow of acoustic energy to the bulk acoustic wave resonator.

2. The device of claim 1, wherein the bulk acoustic wave resonator comprises a bulk acoustic wave resonator gyroscope.

3. The device of claim 2, further comprising one or more electrodes, wherein the bulk acoustic wave resonator gyroscope is capacitively transduced via the one or more electrodes.

4. The device of claim 3, wherein the one or more electrodes include one or more peripheral electrodes.

5. The device of claim 1, further comprising one or more attachment structures that includes one or more selected from the group of: a soft die attach, a hard die attach, an adhesive, a stud bump, or an interposer.

6. The device of claim 1, wherein the one or more attachment structures are disposed below the substrate.

7. The device of claim 1, wherein a first dimension is smaller than a second dimension, the first dimension defined by a first distance from a first end of a first trench to second end of a second trench, the second dimension defined by a second distance from a third end of a first electrode to a fourth end of a second electrode.

8. The device of claim 2, further comprising an attachment structure that includes one or more selected from the group of: a soft die attach, a hard die attach, an adhesive, a stud bump, or an interposer.

9. The device of claim 2, wherein the one or more attachment structures are disposed below the substrate.

10. The device of claim 2, wherein a first dimension is smaller than a second dimension, the first dimension defined by a first distance from a first end of a first trench to a second end of a second trench, the second dimension defined by a second distance from a third end of a first electrode to a fourth end of a second electrode.

11. A device comprising:
a plurality of device components, wherein
a first device component selected from the plurality of device components comprises a plurality of trenches, and
a second device component selected from the plurality of device components is sensitive to acoustic energy, wherein the plurality of trenches are configured to impede the flow of the acoustic energy to the second device component.

12. The device of claim 11, wherein the second device component is mounted on a first surface of the first device component.

13. The device of claim 11, further comprising:
an attachment structure that is not in a direct line of sight from the second device component; and
an underlying support structure that is coupled to the first device component via the attachment structure.

14. The device of claim 11, wherein the first device component includes a cavity disposed below the second device component, and wherein the second device component comprises a bulk acoustic wave resonator.

15. The device of claim 14, wherein the bulk acoustic wave resonator is capacitively transduced by one or more electrodes.

16. A device comprising:
a substrate;
a resonator that is coupled to a first surface of the substrate, the resonator comprising a bulk acoustic wave resonator gyroscope that is capacitively transduced via one or more electrodes; and
a cap structure, wherein the cap structure comprises: one or more trenches that are configured to impede the flow of the acoustic energy to the resonator; and one or more cavities that are configured to impede the flow of the acoustic energy to the resonator.

17. The device of claim 16, wherein at least one trench selected from the one or more trenches is disposed near a corner portion of the cap structure.

18. The device of claim 16, wherein at least one cavity selected from the one or more cavities is disposed in the cap structure at least partially below the resonator.

19. The device of claim 16, wherein the cap structure is disposed below the substrate.

20. The device of claim 16, wherein the resonator is coupled to a first surface of the cap structure.
